(19) United States
(12) Patent Application Publication
(10) Pub. No.: US 2015/0318315 A1
(43) Pub. Date: Nov. 5, 2015

(54) THIN FILM TRANSISTOR ARRAY SUBSTRATE AND METHOD FOR MAKING THE SAME

(71) Applicants: Changyi Su, Shenzhen (CN); Yangling Cheng, Shenzhen (CN)

(72) Inventors: Changyi Su, Shenzhen (CN); Yangling Cheng, Shenzhen (CN)

(21) Appl. No.: 14/349,661

(22) PCT Filed: Feb. 27, 2014
(86) PCT No.: PCT/CN2014/072639

§ 371 Date: Apr. 4, 2014

(30) Foreign Application Priority Data
Feb. 24, 2014 (CN) 201410063283.4

(51) Int. Cl. H01L 27/12; H01L 21/308

(52) U.S. Cl. CPC H01L 27/1288; H01L 27/1262; H01L 21/3081; H01L 27/1248

(57) ABSTRACT

The present application provides a thin film transistor array substrate and a method for making the same. A technical solution of the present application is to divide a removable area from a planarization layer of a thin film transistor array substrate, all organic photoresist material in the removable area is entirely removed, and sealant is directly spread on the protection layer, which is easier to stick, to achieve better sealant adhesion effect. In this way, the whole structure of a TFT-LCD using the thin film transistor array substrate provided by the present application is adhered more firmly. Compared with the prior art, the method of the present application can improve the product pass rate effectively, and is simple and easy to execute.

### FIELD OF THE INVENTION

The present application relates to the field of liquid crystal displays, and more particularly, relates to a thin film transistor array substrate and a method for making the thin film transistor array substrate.

### BACKGROUND OF THE INVENTION

Rapid progress of multimedia society mainly benefits from great progresses of semiconductor components and display devices. In the field of displays, thin film transistor liquid crystal displays (TFT-LCDs), which have the advantages of high image quality, high space utilization rate, low power consumption, and no radiation, have already occupied most of the market.

Generally, a TFT-LCD includes a thin film transistor array substrate, a liquid crystal layer, and a color filter substrate. In the manufacturing process of the TFT-LCD, a sealant layer is usually spread on the thin film transistor array substrate. The color filter substrate is adhered to the thin film transistor array substrate due to the adhesion of the sealant layer, and the liquid crystal layer is sealed between the thin film transistor array substrate and the liquid crystal layer.

Referring to FIG. 1, in a manufacturing process of a conventional TFT-LCD, a method for making a thin film transistor array substrate generally includes the following steps.

Step I: Forming thin film transistors. A specific method of this step is to form grids 111 of the thin film transistors on a top surface of a substrate body 110 using conductive material such as metal, and form an insulation layer 112 on the top surface of the substrate body 110 using insulation material such as silicon oxide or silicon nitride. The insulation layer 112, which is generally called a grid protection layer or a grid dielectric layer in the industry, covers both the top surface of the substrate body 110 and the grids 111 of the thin film transistors. Thus, semiconductor layers 113 of the thin film transistors are formed on portions of a top surface of the insulation layer 112 corresponding to the grids 111 using semiconductor material, and the semiconductor layers 113 serve as transistor channels of the thin film transistors. Finally, drains 114 and sources 115 of the thin film transistors are formed on the semiconductor layers 113 using conductive material such as metal.

Step II: Forming a protection layer 120 on the top surface of the insulation layer 112 using insulation material such as silicon oxide or silicon nitride. The top surface of the insulation layer 112 and the semiconductor layers 113, the drains 114, and the sources 115 formed on the top surface of the insulation layer 112 are all covered by the protection layer 120.

Step III: Forming a planarization layer 130 on a top surface of the protection layer 120 using organic photoresist material.

Step IV: Using a mask 140 to cover a top surface of the planarization layer 130, and exposing a top surface of the mask 140. The mask 140 defines through holes corresponding to the thin film transistors. In the exposure process, portions of the planarization layer 130 covered by the mask 140 are not affected, and portions of the planarization layer 130 aligned with the through holes are exposed and degenerated. For example, the mask 140 defines a through hole 141, as shown in FIG. 1. In the exposure process, a portion of the planarization layer 130 aligned with the through hole 141 is irradiated and degenerated, and thus can be removed by a subsequent etching process. However, the other portions of the planarization layer 130 maintain their original chemical properties, and cannot be removed by the subsequent etching process. A purpose of the exposure process is to form wire holes configured to lead wires from the drains 114 or the sources 115. Therefore, when the mask 140 covers the planarization layer 130, the through hole 141 should be aligned with one of the drains 114 or one of the sources 115 vertically. In this embodiment, the through hole 141 is aligned with one of the sources 115, as shown in FIG. 1.

Step V: After the exposure process, the planarization layer 130 is developed. In the development process, since chemical properties of the portion of the planarization layer 130 aligned with the through hole 141 are changed by irradiation, this portion can be dissolved and removed by etching agent. The other portion of the planarization layer 130 is not irradiated and cannot be dissolved by etching agent, therefore, this portion still covers the protection layer 120. In this way, a connection hole 150, which is aligned with the through hole 141 of the mask 140 (that is, aligned with the source 115 perpendicularly), is formed in the planarization layer 130. A part of the protection layer 120 is exposed from the bottom of the connection hole 150.

Step VI: After forming the connection hole 150 in the planarization layer 130, an etching process is executed. The part of the protection layer 120 exposed from the connection hole 150 is removed, and a wire hole 160 communicating with the connection hole 150 is formed in the protection layer 120 correspondingly. The source 115 is partially exposed via the connection hole 150 and the wire hole 160. In this way, a wire (not shown) led from the source 115 can pass through the connection hole 150 and the wire hole 160 and be electrically connected with other external electronic components, so that the thin film transistor including the source 115 can function.

Step VII: Sealant is spread on the top surface of the rest part of the planarization layer 130, and thus a thin film transistor array substrate is completed. Due to the adhesion of the sealant, a color filter substrate (not shown) can be adhered to the thin film transistor array substrate, and the thin film transistors of the thin film transistor array substrate are sealed between the substrate body 110 and the color filter substrate.

However, in the prior art, the adhesion force between the sealant and the organic photoresist material forming the planarization layer 130 is usually weak, and it is difficult to achieve firm enough adhesion effect. Therefore, when a thin film transistor array substrate made by the aforementioned method is used to manufacture a TFT-LCD, because of the unfirm adhesion, gaps may be formed between the thin film transistor array substrate and a color filter substrate adhered by the sealant, and the thin film transistor array substrate may even entirely separate from the color filter substrate. Thus, the product quality may be adversely affected.

### SUMMARY OF THE INVENTION

The present application is configured to solve this technical problem: aiming at the aforementioned defect in the prior art, a thin film transistor array substrate that has better sealant adhesion effect, is easy to assemble, and is propitious to improve the product pass rate, and a method for making the thin film transistor array substrate, are provided.

A technical solution of the present application configured to solve the aforementioned technical problem is to provide a method for making a thin film transistor array substrate. The method comprises the following steps:

S01, forming thin film transistors on a substrate body, forming a protection layer covering the substrate body and the thin film transistors using insulation material, and forming a planarization layer on the protection layer using organic photoresist material;

S02, dividing the planarization layer into a display area and a removable area, exposing selected portions of the display area completely, and exposing the removable area incompletely;

S03, performing a photoresist development process, forming connection holes in the selected portions of the display area, and partially removing the removable area to form a shielding layer that is thinner than the planarization layer on the protection layer;

S04, forming wire holes communicating with the connection holes and configured to lead wires of the thin film transistors in the protection layer;

S05, after forming the wire holes, removing the shielding layer to partially expose the protection layer and thereby form an adhesion area, and spreading sealant on the adhesion area.

In the method of the present application, the step S02 includes the following sub-steps:

S021: providing a mask, wherein the mask is a gray level mask or a semipermeable membrane mask and includes a light shielding portion that does not allow any light to pass and a semitransparent portion that allows light to partially pass, and the light shielding portion defines exposure holes aligned with the selected portions of the display area; using the light shielding portion to cover the display area, and using the semitransparent portion to cover the removable area;

S022: exposing a top surface of the light shielding portion and a top surface of the semitransparent portion simultaneously, so that the selected portions of the display area are completely exposed by irradiation of exposure light passing through the exposure holes, and the removable area is incompletely exposed by irradiation of exposure light partially passing through the semitransparent portion.

In the method of the present application, in the step S04, the wire holes are formed by means of dry etching.

In the method of the present application, in the step S04, chlorine or sulfur hexafluoride is used as etching gas.

In the method of the present application, in the step S05, the shielding layer is removed by means of an ashing process.

In the method of the present application, in the step S01, forming the thin film transistors on the substrate body includes the following sub-steps:

S011: forming grids of the thin film transistors on the substrate body;

S012: forming an insulation layer covering the substrate body and the grids;

S013: forming semiconductor layers used as transistor channels of the thin film transistors on the insulation layer using semiconductor material;

S014: forming drains and sources of the thin film transistors on the semiconductor layers.

In the method of the present application, the connection holes formed in the step S03 and the wire holes formed in the step S04 are aligned with the drains and/or the sources, and each of the drains and/or the sources is partially exposed by a corresponding connection hole and a corresponding wire hole.

In the method of the present application, in the sub-step S012, the insulation layer is formed by means of a chemical vaporous deposition method.

In the method of the present application, in the step S01, the protection layer is formed by means of a chemical vaporous deposition method.

The present application further provides a thin film transistor array substrate, which comprises a substrate body, thin film transistors formed on the substrate body, a protection layer formed by insulation material and covering the substrate body and the thin film transistors, and a planarization layer formed by organic photoresist material and covering a part of the protection layer. Sealant is spread on another part of the protection layer to form a sealant layer beside the planarization layer.

By implementing the thin film transistor array substrate and the method for making the thin film transistor array substrate of the present application, the following advantages can be achieved: a removable area is divided from the planarization layer, all organic photoresist material in the removable area is entirely removed, and the sealant is directly spread on the protection layer, which is easier to stick, to achieve better sealant adhesion effect. In this way, the whole structure of the TFT-LCD using the thin film transistor array substrate provided by the present application is adhered more firmly. Compared with the prior art, the method of the present application can improve the product pass rate effectively, and is simple and easy to execute.

### BRIEF DESCRIPTION OF THE DRAWINGS

FIG. 1 is a schematic diagram of a manufacturing process of a conventional thin film transistor array substrate.

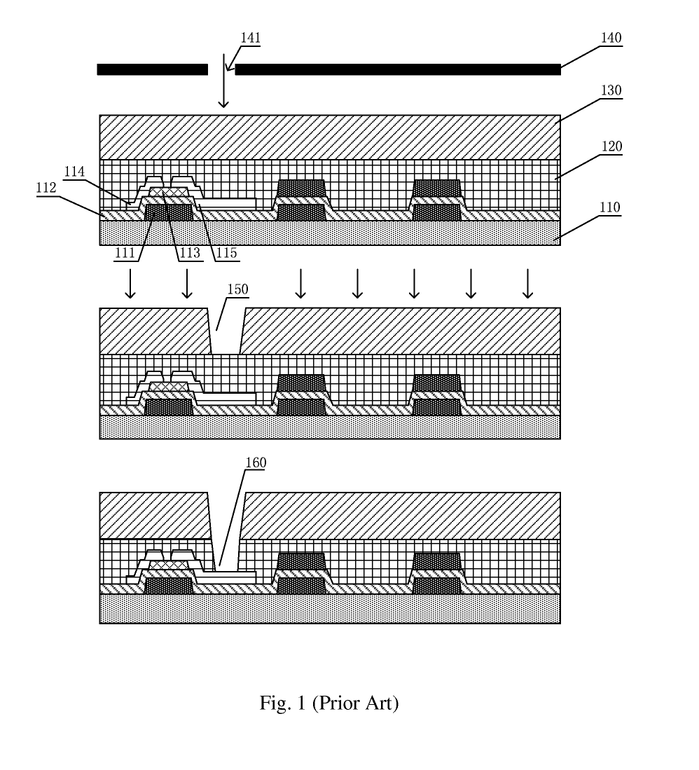

FIG. 2 is a schematic diagram of a manufacturing process of a thin film transistor array substrate of a preferred embodiment of the present application.

FIG. 3 is a cut-away view of the thin film transistor array substrate of the preferred embodiment of the present application.

### DETAILED DESCRIPTION OF THE PREFERRED EMBODIMENT

In order to understand the technical features, purpose and the effect of the present invention more clearly, the preferred specific embodiments of the present invention will be described referring to the drawings.

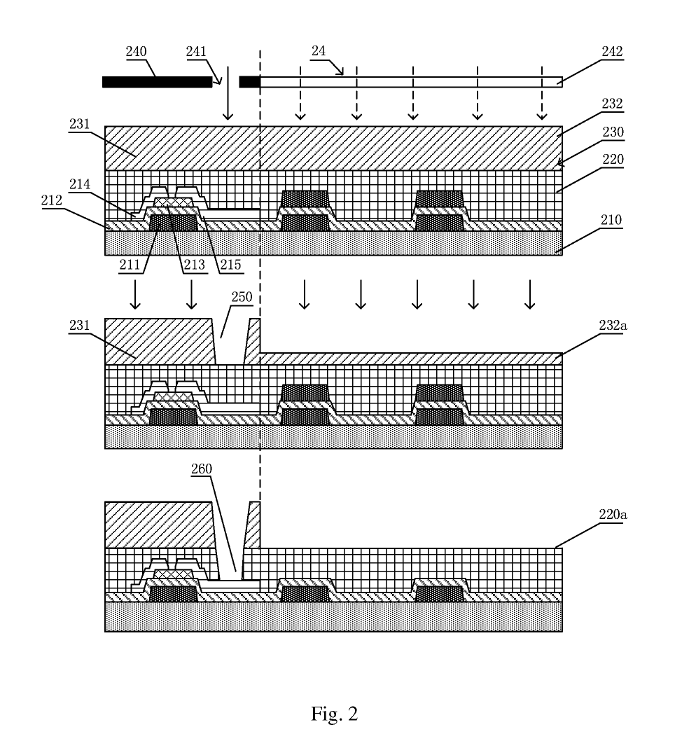

Referring to FIG. 2, one preferred embodiment of the present application provides a method for making a thin film transistor array substrate, wherein the thin film transistor array substrate has better sealant adhesion effect, is easy to assemble, and is propitious to improve the product pass rate. Particularly, the method includes the following steps.

Step S1: Forming thin film transistors on a substrate body. First, a substrate body 210 is provided. The material of the substrate body 210 can be glass, and the specific type of the material can be selected according to the prior art. Afterwards, grids 211 of the thin film transistors are formed on a top surface of the substrate body 210 using conductive material such as metal, and an insulation layer 212 is formed on the top surface of the substrate body 210 using insulation material such as silicon oxide or silicon nitride. The insulation layer 212, which is generally called a grid protection layer or a grid dielectric layer in the industry, covers the top surface of the substrate body 210 and the grids 211 of the thin film transistors. In this embodiment, the insulation layer 212 is formed by means of a chemical vaporous deposition method. Thus, semiconductor layers 213 of the thin film transistors are formed on portions of a top surface of the insulation layer 212 corresponding to the grids 211 using semiconductor material, and the semiconductor layers 213 serve as transistor channels of the thin film transistors. Finally, drains 214 and sources 215 of the thin film transistors are formed on the semiconductor layers 213 using conductive material such as metal.

It should be pointed out that the thin film transistor array substrate should include a number of thin film transistors clearly. However, since all of the thin film transistors have similar structures, as long as a structural schematic view of any one of the thin film transistors is clearly shown, one of ordinary skill in the art can understand the structures of all of the thin film transistors. Therefore, for showing more clearly and more concisely, this embodiment only shows a structural schematic view of one of the thin film transistors. However, one of ordinary skill in the art should obviously know that the number of the thin film transistors can actually be more, and is not limited to one.

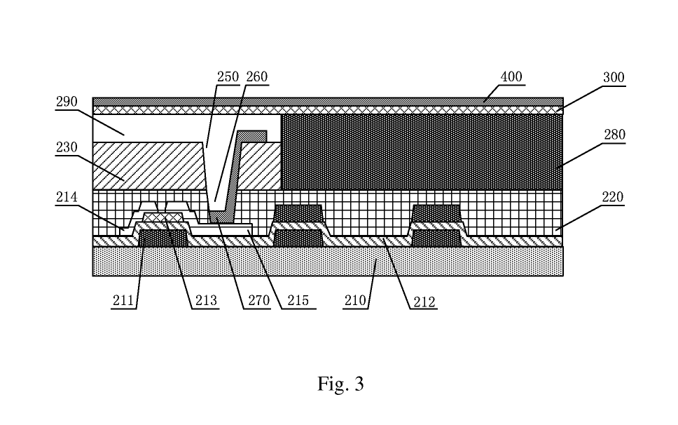

Furthermore, the components of the thin film transistor array substrates shown in FIG. 2 and FIG. 3 may be not drawn according to their real scales. For example, the girds 211, the drains 214, and the sources 215 are much larger than their real sizes. However, the drawings are only used to describe the technical scheme of this embodiment clearly, and therefore they can be different from the real scales.

Step S2: Forming a protection layer 220 on the top surface of the insulation layer 212 using insulation material such as silicon oxide or silicon nitride. The top surface of the insulation layer 212 and the semiconductor layers 213, the drains 214, and the sources 215 formed on the top surface of the insulation layer 212 are all covered by the protection layer 220. In this embodiment, the protection layer 220 is formed by means of a chemical vaporous deposition method too.

Step S3: Forming a planarization layer 230 on a top surface of the protection layer 220 using organic photoresist material. The material type and the forming method of the planarization layer 230 can be in the prior art, and do not need to be detailed here.

Step S4: Dividing the planarization layer 230 into a display area 231 and a removable area 232. In this embodiment, the display area 231 is configured at a central portion of the substrate body 210, and all of the thin film transistors are covered by the display area 231. In following manufacturing processes, a liquid crystal layer (not shown) of a TFT-LCD using the thin film transistor array substrate can be formed on the display area 231. The features and the forming method of the liquid crystal layer can be in the prior art, and do not need to be detailed here. The removable area 232 is configured at a peripheral portion of the substrate body 210, and a shape and a position of the removable area 232 are the same as a shape and a size of a sealant spreading area of the thin film transistor array substrate.

Step S5: Providing a mask 24. The mask 24 is a gray level mask or a semipermeable membrane mask, and includes a light shielding portion 240 that does not allow any light to pass and a semitransparent portion 232 that allows light to partially pass. The technology for forming the light shielding portion 240 and the semitransparent portion 242 on a gray level mask or a semipermeable membrane mask can be in the prior art, one of ordinary skill in the art can realize the technology without any creative work, and therefore the technology does not need to be detailed in this embodiment.

Exposure holes 241 are defined in the light shielding portion 240. Positions of the exposure holes 241 are aligned with selected portions of the display area 231. The selected portions can be portions of the display area 231 which are aligned with the drains 214 or the sources 215 of the thin film transistors. In this embodiment, the selected portions are the portions of the display area 231 which are aligned with the sources 215 of the thin film transistors, that is, the positions of the exposure holes 241 are vertically aligned with the sources 215.

A position of the mask 24 is adjusted, so that the light shielding portion 240 covers a top surface of the display area 231 and the semitransparent portion 242 covers a top surface of the removable area 232.

It should be pointed out that the light shielding portion 240 should define a number of exposure holes 241, because the thin film transistor array substrate includes a number of thin film transistors. The position of each of the exposure holes 241 should be aligned with the drain 214 or the source 215 of one of the thin film transistors. In this embodiment, for showing more clearly and more concisely, FIG. 2 shows only one exposure hole 241 defined in the light shielding portion 240 and aligned with the source 215 of one of the thin film transistors. However, one of ordinary skill in the art should clearly know that the number of the exposure holes 241 can actually be more, and is not limited to one.

Based on basic characteristics of gray level masks or semipermeable membrane masks, when exposure light irradiates the semitransparent portion 242, it can partially pass through the semitransparent portion 242 and incompletely expose the organic photoresist material under the semitransparent portion 242.

Step S6: When the light shielding portion 240 and the semitransparent portion 242 are positioned at correct shielding positions, a top surface of the light shielding portion 240 and a top surface of the semitransparent portion 242 are exposed simultaneously. In the exposure process, portions of the display area 231 covered by the light shielding portion 240 are not affected, maintain their original chemical characteristics, and cannot be removed in a following etching process; however, the selected portions, that is, portions of the display area 231 aligned with the exposure holes 241 of the light shielding portion 240, are completely exposed by irradiation of exposure light passing through the exposure holes 241. The chemical characteristics of the selected portions are completely changed, and thus the selected portions can be completely removed in the following etching process. In the removable area 232, the exposure light partially passes through the semitransparent portion 242 and irradiates the whole removable area 232 with reduced light intensity, that is, the removable area 232 is incompletely exposed. Under the incomplete exposure, the chemical characteristics of the removable area 232 are incompletely changed. In the following etching process, the solubility of the incompletely exposed removable area 232 in the etching agent is less than the solubility of the completely exposed portions of the display area 231 in the etching agent. Therefore, the removable area 232 will be partially removed in the etching process. The thickness of the removable area 232 will be reduced, but the whole removable area 232 cannot be completely removed.

Step S7: After the exposure process, a photoresist development process is applied to the planarization layer 230. In this embodiment, the method for photoresist development is dry etching. Particularly, the method can be plasma etching, sputter etching, gaseous corrosion, and so on. In this embodiment, the gaseous corrosion method is preferred.

In the photoresist development process, the chemical characteristics of the selected portions of the display area 231 (i.e., the portions of the display area 231 aligned with the exposure holes 241) are changed by irradiation, and thus the selected portions can be dissolved and removed by the etching agent. However, the other portions of the display area 231 are not irradiated, and thus these portions cannot be dissolved by the etching agent and still cover the protection layer 220. In this way, connection holes 250, which are aligned with the exposure holes 241 of the light shielding portion 240 (i.e., aligned with the drains 214 and/or the sources 215), are formed in the display area 231. Each of the connection holes 250 exposes a part of the protection layer 220. At the same time, the removable area 232 is partially dissolved and removed by the etching agent in the photoresist development process. Thus, the thickness of the removable area 232 is reduced, and the removable area 232 becomes a shielding layer 232a remaining on the protection layer 220. The shielding layer 232a is thinner than the planarization layer 230.

In this embodiment, the aforementioned two operations of the photoresist development process, that is, forming the connection holes 250 and partially removing the organic photoresist material of the removable area 232, can be simultaneously performed using only one mask 24. If the two operations (i.e., forming the connection holes 250 and partially removing the organic photoresist material of the removable area 232) are respectively performed in two independent processes, the operations will consume more time and cost than the technical solution of this embodiment.

Step S8: After forming the connection holes 250 and the shielding layer 232a, another etching process is performed to remove the parts of the protection layer 220 exposed by the connection holes 250 and thereby form wire holes 260 communicating with the connection holes 250 and aligned with the drains 214 and/or the sources 215. Each of the drains 214 and/or the sources 215 is partially exposed by a corresponding connection hole 250 and a corresponding wire hole 260. In this way, a wire (not shown) led from the drain 214 or the source 215 can pass through the connection hole 250 and the wire hole 260 and be electrically connected with other external electronic components (not shown), so that the thin film transistor including the drain 214 or the source 215 can function. At the same time, the portions of the protection layer 220 shielded by the shielding layer 232a are protected by the shielding layer 232a and cannot be removed by the etching process of this step. In this embodiment, the method of the etching process of this step is dry etching, too. Particularly, the method can be plasma etching, sputter etching, gaseous corrosion, and so on. In this embodiment, the gaseous corrosion method is preferred. The etching gas can be chlorine or sulfur hexafluoride.

Step S9: After forming the wire holes 260, the shielding layer 232a is heated in ashing reaction gas such as oxygen, that is, the ashing process of the shielding layer 232a is performed in oxygen. After the ashing process, the shielding layer 232a can be entirely removed, so that the portions of the protection layer 220 which are once covered by the removable area 232 of the planarization layer 230 are entirely exposed and form an adhesion area 220a. In this embodiment, when the etching process of the step S8 is completed, the substrate body 210 does not require being moved, and the ashing process of the step S9 can be immediately performed as soon as oxygen is introduced into the same reaction chamber as that for performing the etching process of the step S8. Thus, both time and work can be saved.

Step S10: Sealant is spread on the adhesion area 220a, a conventional color filter substrate (not shown) is attached to the thin film transistor array substrate by the viscosity of the sealant, and the thin film transistors are packaged between the substrate body 210 and the color filter substrate. Thus, the whole making process is completed. Based on widely used conventional sealant materials, it is easy to know that adhesive force between the sealant and the organic photoresist material for forming the planarization layer 230 is generally less than adhesive force between the sealant and the insulation materials for forming the protection layer 220, such as silicon oxide or silicon nitride. Therefore, compared with the prior art, the thin film transistor array substrate manufactured according to the method of this embodiment has better sealant adhesive effect and can improve the product pass rate effectively.

Referring to FIG. 3, another preferred embodiment of the present application provides a thin film transistor array substrate. The thin film transistor array substrate can be manufactured by the method provided by the aforementioned embodiment. In particular, the thin film transistor array substrate includes a substrate body 210, a top surface of the substrate body 210 is provided with grids 211 of thin film transistors, and the grids 211 and other portions of the top surface of the substrate body 210 are all covered by an insulation layer 212. Portions of a top surface of the insulation layer 212 corresponding to the grids 211 are provided with semiconductor layers 213 of the thin film transistors. Top surfaces of the semiconductor layers 213 are provided with drains 214 and sources 215 of the thin film transistors. Materials and manufacturing methods of the substrate body 210, the insulation layer 212, the grids 211, the semiconductor layers 213, the drains 214, and the sources 215 are all the same as that of the method of the aforementioned embodiment, and do not need to be detailed here.

The top surface of the insulation layer 212 is further provided with a protection layer 220, and the top surface of the insulation layer 212 and the semiconductor layers 213, the drains 214, and the sources 215 formed on the top surface of the insulation layer 212 are all covered by the protection layer 220. Furthermore, portions of the protection layer 220 corresponding to the drains 214 and/or the sources 215 of the thin film transistors define wire holes 260, and each of the drains 214 and/or the sources 215 is partially exposed by a corresponding wire hole 260. In this embodiment, it is a source 215 that is partially exposed by a wire hole 260, as shown in FIG. 3. Material and a manufacturing method of the protection layer 220 are the same as that of the method of the aforementioned embodiment, and do not need to be detailed here.

A part of a top surface of the protection layer 220 is provided with a planarization layer 230, and a distribution area of the planarization layer 230 overlaps a distribution area of the thin film transistors. The planarization layer 230 defines connection holes 250. The connection holes 250 are respectively vertically aligned with the wire holes 260, and the bottom of each of the connection holes 250 communicates with a corresponding wire hole 260. Material and a manufacturing method of the planarization layer 230, and a manufacturing method of the connection holes 250 are all the same as that of the method of the aforementioned embodiment, and do not need to be detailed here.

As shown in FIG. 3, a wire 270 is received in a connection hole 250 and a wire hole 260. One end of the wire 270 is electrically connected to a part of a source 215 of a thin film transistor exposed via the bottom of the wire hole 260, and the other end of the wire 270 extends to the top surface of the planarization layer 230 and is electrically connected with other external electronic components (not shown), so that the thin film transistor can function. In other embodiments, if a drain 214 of a thin film transistor is partially exposed via a wire hole 260 and a connection hole 250, the wire 270 can also be used to electrically connect the drain 214 with other external electronic components. If a drain 214 and a source 215 of a thin film transistor are respectively partially exposed via two wire holes 260 and two connection holes 250 communicating with the two wire holes 260 respectively, two wires 270 can be provided correspondingly, so that the drain 214 and the source 215 can be respectively electrically connect with other external electronic components.

It should be pointed out that the thin film transistor array substrate should obviously include a number of thin film transistors and a number of wires 270 corresponding to the thin film transistors. However, since all of the thin film transistors have similar structures and all of the wires 270 have similar structures too, as long as a structural schematic view of any one of the thin film transistors is clearly shown, one of ordinary skill in the art can understand the structures of all of the thin film transistors. Therefore, in this embodiment, for showing more clearly and more concisely, FIG. 3 only shows a structural schematic view of one of the thin film transistors and one wire 270 corresponding to the thin film transistor. However, one of ordinary skill in the art should obviously know that the number of the thin film transistors and the number of the wires 270 can actually be more, and are not limited to one.

Sealant is spread on another part of the top surface of the protection layer 220 to form a sealant layer 280 beside the planarization layer 230. Based on widely used conventional sealant materials, it is easy to know that adhesive force between the sealant and the organic photoresist material for forming the planarization layer 230 is generally less than adhesive force between the sealant and the insulation materials for forming the protection layer 220, such as silicon oxide or silicon nitride. Therefore, compared with conventional thin film transistor array substrates, which include sealant stuck to planarization layers formed by organic photoresist material, the thin film transistor array substrate of this embodiment has better sealant adhesive effect and can improve the product pass rate effectively.

The thin film transistor array substrate of this embodiment further includes a color filter substrate 300 and a protection panel 400. The color filter substrate 300 can be a conventional color filter, and the protection panel 400 can be a conventional glass substrate. Therefore, features of the color filter substrate 300 and the protection panel 400 do not need to be detailed here. The color filter substrate 300 is stuck to a top surface of the sealant layer 280, and the thin film transistors are all packaged between the substrate body 210 and the color filter substrate 300. The protection panel 400 is fixedly mounted on a top surface of the color filter substrate 300 to protect the color filter substrate 300, the planarization layer 230, and the thin film transistors. In this embodiment, a thickness of the sealant layer 280 is greater than a thickness of the planarization layer 230, so that the color filter substrate 300 is apart from the planarization layer 230 and an assembly space 290 is thereby formed between the color filter substrate 300 and the planarization layer 230. The assembly space 290 can be used to package a liquid crystal layer (not shown) of the thin film transistor array substrate and other necessary assembly structures (not shown). The liquid crystal layer and the assembly structures are all in the prior art, and thus do not need to be detailed here.

In the thin film transistor array substrate and the method for making the thin film transistor array substrate of the present application, the removable area 232 is divided from the planarization layer 230, all organic photoresist material in the removable area 232 is entirely removed by two steps, and the sealant is spread on the protection layer 220, which is easier to stick, to achieve better sealant adhesion effect. In this way, the whole structure of the TFT-LCD using the thin film transistor array substrate of the present application is adhered more firmly. Compared with the prior art, the product pass rate can be improved effectively. Furthermore, in the two steps for removing the organic photoresist material in the removable area 232, the former step can be merged with the etching process for forming the connection holes 250 in the planarization layer 230. In this way, the whole process is simplified, and thus the method is simple and easy to execute.

While the present invention has been described with the drawings to preferred embodiments which is merely a hint rather than a limit, it will be understood by those skilled in the art that various changes may be made and equivalents may be substituted without departing from the scope of the present invention. But all the changes will be included within the scope of the appended claims.

What is claimed is:

1. A method for making a thin film transistor array substrate, comprising the following steps:
S01, forming thin film transistors on a substrate body, forming a protection layer covering the substrate body and the thin film transistors using insulation material, and forming a planarization layer on the protection layer using organic photoresist material;
S02, dividing the planarization layer into a display area and a removable area, exposing selected portions of the display area completely, and exposing the removable area incompletely;
S03, performing a photoresist development process, forming connection holes in the selected portions of the display area, and partially removing the removable area to form a shielding layer that is thinner than the planarization layer on the protection layer;
S04, forming wire holes communicating with the connection holes and configured to lead wires of the thin film transistors in the protection layer;
S05, after forming the wire holes, removing the shielding layer to partially expose the protection layer and thereby form an adhesion area, and spreading sealant on the adhesion area.

2. The method according to claim 1, wherein, the step S02 includes the following sub-steps:
S021: providing a mask, wherein the mask is a gray level mask or a semipermeable membrane mask and includes a light shielding portion that does not allow any light to pass and a semitransparent portion that allows light to partially pass, and the light shielding portion defines exposure holes aligned with the selected portions of the display area; using the light shielding portion to cover the display area, and using the semitransparent portion to cover the removable area;
S022: exposing a top surface of the light shielding portion and a top surface of the semitransparent portion simultaneously, so that the selected portions of the display area are completely exposed by irradiation of exposure light passing through the exposure holes, and the removable area is incompletely exposed by irradiation of exposure light partially passing through the semitransparent portion.

3. The method according to claim 1, wherein, in the step S04, the wire holes are formed by means of dry etching.

4. The method according to claim 3, wherein, in the step S04, chlorine or sulfur hexafluoride is used as etching gas.

5. The method according to claim 1, wherein, in the step S05, the shielding layer is removed by means of an ashing process.

6. The method according to claim 1, wherein, in the step S01, forming the thin film transistors on the substrate body includes the following sub-steps:
S011: forming grids of the thin film transistors on the substrate body;
S012: forming an insulation layer covering the substrate body and the grids;
S013: forming semiconductor layers used as transistor channels of the thin film transistors on the insulation layer using semiconductor material;
S014: forming drains and sources of the thin film transistors on the semiconductor layers.

7. The method according to claim 6, wherein, the connection holes formed in the step S03 and the wire holes formed in the step S04 are aligned with the drains and/or the sources, and each of the drains and/or the sources is partially exposed by a corresponding connection hole and a corresponding wire hole.

8. The method according to claim 6, wherein, in the sub-step S012, the insulation layer is formed by means of a chemical vaporous deposition method.

9. The method according to claim 1, wherein, in the step S01, the protection layer is formed by means of a chemical vaporous deposition method.

10. A thin film transistor array substrate, comprising:
a substrate body;
thin film transistors formed on the substrate body;
a protection layer formed by insulation material and covering the substrate body and the thin film transistors; and
a planarization layer formed by organic photoresist material and covering a part of the protection layer;
wherein, sealant is spread on another part of the protection layer to form a sealant layer beside the planarization layer.
